(19) United States
(12) Patent Application Publication
(10) Pub. No.: US 2025/0048734 A1
(43) Pub. Date: Feb. 6, 2025

(54) DISPLAY PANEL AND MANUFACTURING METHOD THEREOF

(71) Applicant: Samsung Display Co., Ltd., Yongin-Si (KR)

(72) Inventors: Yong Hoon KWON, Yongin-si (KR); Byung Hoon KIM, Yongin-si (KR); Tae Oh KIM, Yongin-si (KR)

(21) Appl. No.: 18/626,325

(22) Filed: Apr. 4, 2024

(30) Foreign Application Priority Data
Jul. 31, 2023 (KR) 10-2023-0099907

(51) Int. Cl. H01L 27/12

(52) U.S. Cl. CPC H01L 27/1218; H01L 27/1262; H01L 27/124

(57) ABSTRACT

A display panel is disclosed that includes: a base substrate, at least one via hole penetrating the base substrate, and first laser-induced graphene formed on a first surface of the base substrate adjacent to the at least one via hole.

### CROSS-REFERENCE TO RELATED APPLICATION(S)

The application claims priority to Korean Patent Application No. 10-2023-0099907, filed Jul. 31, 2023, and all the benefits accruing therefrom under 35 U.S.C. § 119, the content of which in its entirety is herein incorporated by reference.

### BACKGROUND

### 1. Field

The present disclosure relates to a display panel and a manufacturing method of the display panel.

### 2. Description of the Related Art

As information technology develops, the importance of a display device as a connection medium between a user and information is being emphasized. In response to this, the use of display devices such as a liquid crystal display device and an organic light emitting display device is increasing.

A display device may include a display panel. The display panel may display an image based on an image signal (or data signal) provided from a driving integrated circuit.

### SUMMARY

Embodiments may provide a display panel and a manufacturing method of the display panel, which can readily form wirings connected to a data driving integrated circuit.

An embodiment of a display panel includes: a base substrate, at least one via hole penetrating the base substrate, and first laser-induced graphene formed on a first surface of the base substrate adjacent to the at least one via hole.

The first laser-induced graphene may have hydrophilic properties.

The first surface may include a side surface, a portion of an upper surface, and a portion of a lower surface of the base substrate adjacent to the at least one via hole.

The display panel may further include at least one wiring corresponding to the at least one via hole.

The at least one wiring may include at least one of conductive ink and conductive resin.

The at least one wiring may be in contact with the first laser-induced graphene.

The display panel may further include second laser-induced graphene formed on a second surface of the base substrate spaced apart from the at least one via hole and not overlapping the first surface.

The second laser-induced graphene may have water-repellent properties.

The second surface may include a portion of an upper surface of the base substrate spaced apart from the at least one via hole.

The second laser-induced graphene may be in contact with the first laser-induced graphene.

An embodiment of a method of manufacturing a display panel includes: forming at least one via hole penetrating a base substrate, and forming first laser-induced graphene by irradiating a carbon dioxide laser together with a first gas to a first area overlapping the at least one via hole and a portion of the base substrate adjacent to the at least one via hole.

The first laser-induced graphene may be formed on a side surface, a portion of an upper surface, and a portion of a lower surface of the base substrate adjacent to the at least one via hole.

The first gas may include air or oxygen.

The first laser-induced graphene may have hydrophilic properties.

The method of manufacturing the display panel may further include forming at least one wiring corresponding to the at least one via hole, and the at least one wiring may be in contact with the first laser-induced graphene.

The method of manufacturing the display panel may further include forming second laser-induced graphene by irradiating a carbon dioxide laser together with a second gas to a second area spaced apart from the at least one via hole and overlapping a portion of the base substrate.

The second laser-induced graphene may be formed on a portion of an upper surface of the base substrate spaced apart from the at least one via hole.

The second gas may include at least one of argon and hydrogen.

The second laser-induced graphene may have water-repellent properties.

The method of manufacturing the display panel may further include forming at least one wiring corresponding to the at least one via hole, and the at least one wiring may be in contact with the first laser-induced graphene and may not contact the second laser-induced graphene.

### BRIEF DESCRIPTION OF THE DRAWINGS

The above and other features of embodiments of the present disclosure will become more apparent by describing in further detail embodiments thereof with reference to the accompanying drawings, in which:

FIG. 1 is a diagram illustrating an embodiment of a display device.

FIG. 2 is a diagram illustrating an embodiment of a display panel.

FIG. 3 is a diagram illustrating an embodiment of a display panel.

FIG. 4 is a diagram illustrating an embodiment of a display panel.

FIG. 5 is a block diagram illustrating an embodiment of a method of manufacturing a display panel.

FIGS. 6 to 10 are diagrams for schematically illustrating an embodiment of a method of manufacturing a display panel.

### DETAILED DESCRIPTION OF THE ILLUSTRATED EMBODIMENTS

Embodiments will now be described more fully hereinafter with reference to the accompanying drawings, in which the various embodiments are shown. The inventive concepts may, however, be embodied in many different forms, and should not be construed as limited to the embodiments set forth herein. Rather, these embodiments are provided so that this disclosure will be thorough and complete, and will fully convey the scope of the inventive concepts to those skilled in the art.

Like numbers refer to like elements throughout. In the drawings, the thickness of certain lines, layers, components, elements or features may be exaggerated for clarity. It will be understood that, although the terms “first”, “second”, etc. may be used herein to describe various elements, these elements should not be limited by these terms. These terms are only used to distinguish one element from another element. Thus, a “first” element discussed below could also be termed a “second” element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

It will be further understood that the terms “comprises,” “comprising,” “includes,” and “including”, when used in this specification, specify the presence of stated features, integers, steps, operations, elements, or components, but do not preclude the presence or addition of one or more other features, integers, steps, operations, elements, components, or groups thereof.

In the entire specification, when an element is referred to as being “connected” or “coupled” to another element, it can be directly connected or coupled to the another element or be indirectly connected or coupled to the another element with one or more intervening elements interposed therebetween.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments will be described in detail with reference to the accompanying drawings.

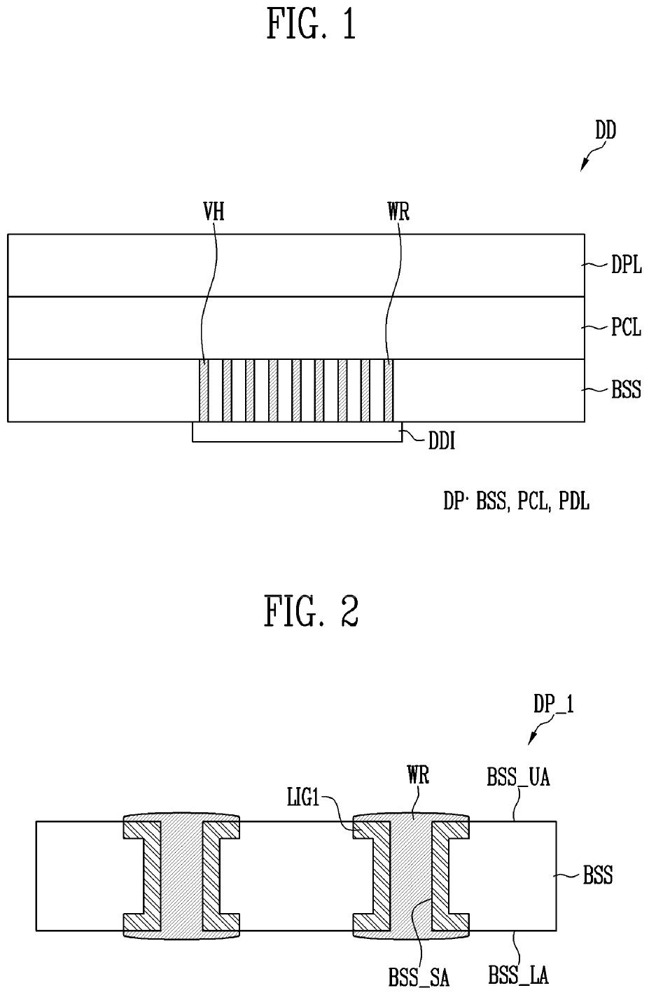

FIG. 1 is a diagram illustrating an embodiment of a display device.

Referring to FIG. 1, the display device DD according to an example may include a display panel DP and a data driving integrated circuit DDI.

The display device DD may be a device that is activated according to an electrical signal and displays an image. For example, the display device DD may be used as a display screen for portable electronic devices such as a mobile phone, a smart phone, a tablet personal computer (PC), a mobile communication terminal, an electronic notebook, an e-book, a portable multimedia player (PMP), a navigation device, and an ultra mobile PC (UMPC). In addition, the display device DD may be used as a display screen for various products such as television, a laptop, a monitor, a billboard, and an internet of thing (IOT).

The display panel DP may be a light emitting type display panel. For example, the display panel DP may be an organic light emitting display panel, an inorganic light emitting display panel, a micro LED display panel, or a nano LED display panel. The display panel DP may be a flexible display panel.

The display panel DP may include a base substrate BSS, a pixel circuit layer PCL, and a display element layer DPL.

The base substrate BSS may provide a base surface on which the pixel circuit layer PCL is disposed. The base substrate BSS may be a flexible substrate capable of bending, folding, rolling, etc.

At least one via hole VH may be formed in the base substrate BSS. At least one via hole VH may serve as an electrical connection path connecting multiple components (or layers). For example, at least one via hole VH may serve as an electrical connection path connecting the pixel circuit layer PCL and the data driving integrated circuit DDI. To this end, at least one via hole VH may be formed to penetrate the base substrate BSS. The number of via holes VH shown in FIG. 1 is only an example, and the number of the vial holes VH is not limited thereto.

A wiring WR may serve to transmit a data signal (or data voltage) supplied from the data driving integrated circuit DDI to the pixel circuit layer PCL. The wiring WR may be disposed in at least one via hole VH. For example, the wiring WR may be formed in at least one corresponding via hole VH. The wiring WR may include a conductive material. That is, at least one via hole VH may be filled with a conductive material so that the pixel circuit layer PCL and the data driving integrated circuit DDI may be electrically connected to each other. FIG. 1 show a case in which the wiring WR is not disposed in the leftmost via hole VH, but this is for convenience of description, and the wiring WR may also be disposed in the leftmost via hole VH.

The pixel circuit layer PCL may be disposed on the base substrate BSS. The pixel circuit layer PCL may include a pixel circuit configured to drive a light emitting element. For example, the pixel circuit may include a transistor that is connected to the wiring WR and receives the data signal (or data voltage) transmitted from the data driving integrated circuit DDI through the wiring WR. In addition, the pixel circuit may further include a transistor, a storage capacitor, etc. that control the current flowing through the light emitting element in response to the data signal (or data voltage).

The display element layer DPL may be disposed on the pixel circuit layer PCL. The display element layer DPL may include the light emitting element that emits light based on an electrical signal provided from the pixel circuit layer PCL. For example, the light emitting element may be an organic light emitting element, an inorganic light emitting element, an organic-inorganic light emitting element, a quantum dot light emitting element, a micro LED light emitting element, or a nano LED light emitting element.

In addition, the display panel DP may further include a thin film encapsulation layer disposed on the display element layer DPL to protect the light emitting element, a light control layer disposed on the thin film encapsulation layer to change the properties of light emitted from the light emitting element, and the like.

The data driving integrated circuit DDI may be disposed below the display panel DP. For example, the data driving integrated circuit DDI may be disposed on a portion of a lower surface BSS_LA (see FIG. 2) of the base substrate BSS. The data driving integrated circuit DDI may be connected to the wiring WR. The data driving integrated circuit DDI may generate an analog image data signal based on a digital image data signal transmitted from a timing controller and a gamma voltage transmitted from a power supply. Here, the analog image data signal may refer to the data signal (or data voltage) described above. That is, the data driving integrated circuit DDI may generate the data signal (or data voltage) and supply the data signal (or data voltage) to the wiring WR.

Meanwhile, the wiring WR may be formed by filling a corresponding via hole VH with a conductive material, drying and curing the conductive material. In this case, the number of via holes VH may be several thousand, and the size of the via holes VH may be as small as a micro level. Because of this, it may be difficult to quickly and accurately fill each via hole VH with a conductive material, making it difficult to form the wiring WR.

Additionally, a conductive material with a high viscosity may not properly fill the via hole VH, and a conductive material with a low viscosity may pass through the via hole VH, making it difficult to form the wiring WR.

FIG. 2 is a diagram illustrating an embodiment of a display panel.

FIG. 2 representatively shows the base substrate BSS among components of the display panel DP shown in FIG. 1.

Referring to FIG. 2, the display panel DP_1 according to an embodiment may include a base substrate BSS, at least one via hole VH (see FIG. 1) penetrating the base substrate BSS, first laser-induced graphene LIG1, and at least one wiring WR.

In an embodiment, the base substrate BSS may be composed of a single layer.

In an embodiment, the base substrate BSS may be made of a polymer material including at least one of polyimide, polycarbonate, polyether sulfone, polyethylene terephthalate, polyethylene naphthalate, and polyarylate.

In an embodiment, the first laser-induced graphene LIG1 may refer to graphene formed by irradiating a laser to a surface of the base substrate BSS. For example, when a laser is irradiated to the surface of the base substrate BSS made of the polymer material, the temperature of the surface of the base substrate BSS to which the laser is irradiated rises instantaneously, and the bond or arrangement of carbon atoms is modified to form the graphene. That is, the first laser-induced graphene LIG1 may mean that a specific surface of the base substrate BSS to which the laser is irradiated is patterned with graphene.

In an embodiment, the first laser-induced graphene LIG1 may be formed on a first surface of the base substrate BSS adjacent to at least one via hole VH.

The first surface may include a side surface BSS_SA of the base substrate BSS adjacent to at least one via hole VH. The side surface BSS_SA of the base substrate BSS may be an area exposed by forming at least one via hole VH penetrating the base substrate BSS. The side surface BSS_SA of the base substrate BSS may be an area adjacent to an inner surface of at least one via hole VH. That is, the side surface BSS_SA of the base substrate BSS may be patterned with the first laser-induced graphene LIG1.

The first surface may include a portion of an upper surface BSS_UA and a portion of a lower surface BSS_LA of the base substrate BSS adjacent to at least one via hole VH. A portion of the upper surface BSS_UA of the base substrate BSS may be an area adjacent to an entrance of at least one via hole VH. A portion of the lower surface BSS_LA of the base substrate BSS may be an area adjacent to an exit of at least one via hole VH. That is, a portion of the upper surface BSS_UA and a portion of the lower surface BSS_LA of the base substrate BSS may be patterned with the first laser-induced graphene LIG1. FIG. 2 shows a case where a portion of the upper surface BSS_UA and a portion of the lower surface BSS_LA of the base substrate BSS are patterned with the first laser-induced graphene LIG1. However, a portion of the upper surface BSS_UA or a portion of the lower surface BSS_LA of the base substrate BSS may be patterned with the first laser-induced graphene LIG1.

In an embodiment, the first laser-induced graphene LIG1 may have hydrophilic properties. For example, the first laser-induced graphene LIG1 may be formed to have hydrophilic properties when the conductive material constituting at least one wiring WR has hydrophilic properties. However, the first laser-induced graphene LIG1 may be formed to have water-repellent properties when the conductive material constituting at least one wiring WR has water-repellent properties.

When the first laser-induced graphene LIG1 has hydrophilic properties, a hydrophilic region may be formed on an inner surface of at least one via hole VH. Therefore, when a conductive material having hydrophilic properties is filled in at least one via hole VH, the conductive material sticks to the first laser-induced graphene LIG1 regardless of the viscosity of the conductive material, so that at least one wiring WR can be formed easily and quickly.

When the first laser-induced graphene LIG1 has hydrophilic properties, a hydrophilic region may be formed in an area adjacent to the inlet and outlet of at least one via hole VH. Therefore, even if the conductive material having hydrophilic properties is not precisely discharged to correspond to the inlet (or outlet) of the via hole VH, the first laser-induced graphene LIG1 induces the movement of the conductive material so that at least one via hole VH can be filled with the conductive material. That is, even if the conductive material is not precisely discharged, at least one wiring WR can be formed easily and quickly.

In an embodiment, at least one wiring WR may be disposed in a corresponding at least one via hole VH (see FIG. 1) and may be in contact with the first laser-induced graphene LIG1. This is because, as described above, the conductive material having hydrophilic properties and constituting at least one wiring WR sticks to the first laser-induced graphene LIG1 having hydrophilic properties.

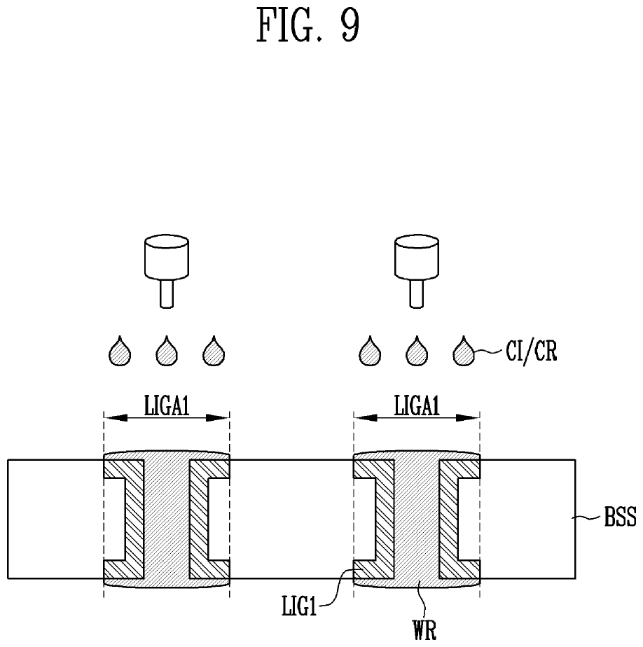

At least one wiring WR may include at least one of conductive ink CI (see FIG. 9) and conductive resin CR (see FIG. 9). For example, the conductive ink CI may include at least one of silver ink, polymer ink, carbon nanotube ink, carbon and graphene ink, dielectric ink, and copper ink. For example, the conductive resin CR may be a resin composition in which at least one conductive additive selected from carbon black, carbon fiber, metal powder, metal-coated inorganic powder, and metal fiber is mixed with a thermoplastic resin.

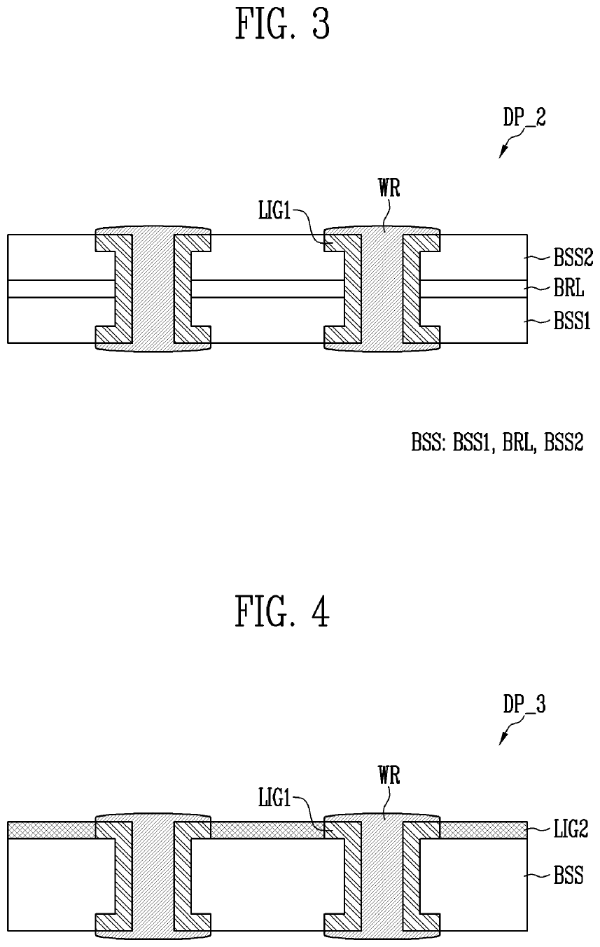

FIG. 3 is a diagram illustrating an embodiment of a display panel. FIG. 3 representatively shows the base substrate BSS among components of the display panel DP shown in FIG. 1. With respect to FIG. 3, content that overlaps with FIG. 2 will be omitted and differences will be mainly explained.

Referring to FIG. 3, in an embodiment, the base substrate BSS may be composed of multiple layers. For example, the base substrate BSS may include a first base substrate BSS1, a barrier layer BRL, and a second base substrate BSS2.

The first base substrate BSS1 may provide a base surface on which the barrier layer BRL is disposed. The first base substrate BSS1 may be a flexible substrate capable of bending, folding, rolling, etc. For example, the first base substrate BSS1 may be made of a polymer material including at least one of polyimide, polycarbonate, polyether sulfone, polyethylene terephthalate, polyethylene naphthalate, and polyarylate.

The barrier layer BRL may be disposed on the first base substrate BSS1. The barrier layer BRL may cover the first base substrate BSS1. The barrier layer BRL may prevent moisture or air from penetrating from outside. The barrier layer BRL may include an inorganic material. For example, the barrier layer BRL may include at least one of silicon oxide (SiOx), silicon nitride (SiNx), and silicon oxynitride (SiOxNy).

The second base substrate BSS2 may be disposed on the barrier layer BRL. The second base substrate BSS2 may be a flexible substrate capable of bending, folding, rolling, etc. For example, the second base substrate BSS2 may be made of a polymer material including at least one of polyimide, polycarbonate, polyether sulfone, polyethylene terephthalate, polyethylene naphthalate, and polyarylate. The second base substrate BSS2 may include substantially the same polymer material as the first base substrate BSS1, but the second base substrate BSS2 is not limited thereto.

FIG. 4 is a diagram illustrating an embodiment of a display panel. FIG. 4 representatively shows the base substrate BSS among components of the display panel DP shown in FIG. 1. With respect to FIG. 4, content that overlaps with FIG. 2 will be omitted and differences will be mainly explained.

Referring to FIG. 4, the display panel DP_3 according to an embodiment may further include second laser-induced graphene LIG2.

In an embodiment, the second laser-induced graphene LIG2 may refer to graphene formed by irradiating a laser to a surface of the base substrate BSS on which the first laser-induced graphene LIG1 is not formed. That is, the second laser-induced graphene LIG2 may not overlap the first laser-induced graphene LIG1. The second laser-induced graphene LIG2 may be formed in the same method as the first laser-induced graphene LIG1 described above.

In an embodiment, the second laser-induced graphene LIG2 may be formed on a second surface of the base substrate BSS spaced apart from the at least one via hole VH (see FIG. 1).

The second surface may be an area that does not overlap the first surface described above. The second surface may include a portion of the upper surface BSS_UA (see FIG. 2) of the base substrate BSS spaced apart from at least one via hole VH. The second surface may include a portion of the upper surface BSS_UA of the base substrate BSS on which the first laser-induced graphene LIG1 is not formed. That is, a portion of the upper surface BSS_UA of the base substrate BSS may be patterned with the second laser-induced graphene LIG2 in contact with the first laser-induced graphene LIG1. FIG. 4 shows a case where a portion of the upper surface BSS_UA of the base substrate BSS is patterned with the second laser-induced graphene LIG2. However, a portion of the lower surface BSS_LA (see FIG. 2) of the base substrate BSS spaced apart from at least one via hole VH may also be patterned with the second laser-induced graphene LIG2.

In an embodiment, the second laser-induced graphene LIG2 may have different chemical properties from the first laser-induced graphene LIG1. For example, when the first laser-induced graphene LIG1 has hydrophilic properties, the second laser-induced graphene LIG2 may have water-repellent properties. Conversely, when the first laser-induced graphene LIG1 has water-repellent properties, the second laser-induced graphene LIG2 may have hydrophilic properties.

When the second laser-induced graphene LIG2 has water-repellent properties, a water-repellent region may be formed in an area spaced apart from at least one via hole VH. Therefore, when a conductive material having hydrophilic properties is discharged to the water-repellent region, the second laser-induced graphene LIG2 may reject the conductive material. As a result, because the conductive material does not stick to the second laser-induced graphene LIG2 but moves to stick to the first laser-induced graphene LIG1, at least one via hole VH may be filled with the conductive material. That is, even if the conductive material is discharged over a large area, at least one wiring WR can be easily formed.

Meanwhile, the second laser-induced graphene LIG2 may also be included in the display panel DP_2 (see FIG. 3) including the base substrate BSS having a multilayer structure.

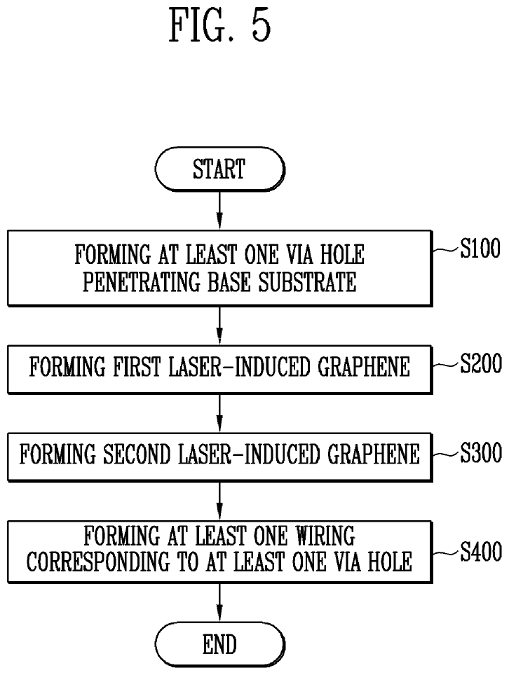

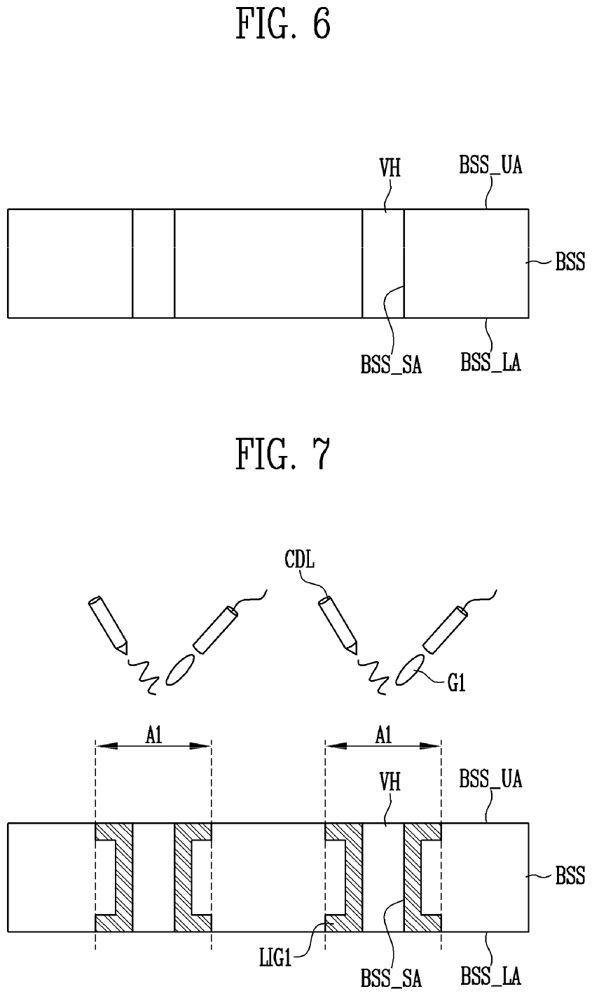

FIG. 5 is a block diagram illustrating an embodiment of a method manufacturing of a display panel. FIGS. 6 to 10 are diagrams for schematically illustrating an embodiment of a method of manufacturing a display panel.

Referring to FIGS. 5 and 6, the manufacturing method of the display panel according to embodiments may include forming at least one via hole VH penetrating a base substrate BSS (S100).

At least one via hole VH may be formed through various methods, such as exposing and developing photoresist, laser etching, and the like. At least one via hole VH penetrating the base substrate BSS may be formed to expose an upper surface BSS_UA, a lower surface BSS_LA, and a side surface BSS_SA of the base substrate BSS. As shown in FIG. 6, the base substrate BSS may have a single-layer structure or a multi-layer structure (see FIG. 3).

Referring to FIGS. 5 and 7, the manufacturing method of the display panel according to embodiments may include forming first laser-induced graphene LIG1 (S200).

The first laser-induced graphene LIG1 may be formed by irradiating a carbon dioxide laser CDL together with a first gas G1 to a first area A1 overlapping at least one via hole VH and a portion of the base substrate BSS adjacent to the at least one via hole VH.

A portion of the base substrate BSS overlapping the first area A1 may include the side surface BSS_SA, a portion of the upper surface BSS_UA, and a portion of the lower surface BSS_LA of the base substrate BSS. When the carbon dioxide laser CDL is irradiated to the first area A1 together with the first gas G1, the first laser-induced graphene LIG1 may be formed on the side surface BSS_SA, the portion of the upper surface BSS_UA, and the portion of the lower surface BSS_LA of the base substrate BSS.

In an embodiment, a wavelength of a laser beam irradiated from the carbon dioxide laser CDL may be 10 to 11 μm. Preferably, the wavelength of the laser beam irradiated from the carbon dioxide laser CDL may be 10.6 μm.

Depending on the type of gas irradiated together with the carbon dioxide laser CDL, chemical properties of graphene formed on a surface of the base substrate BSS may be determined. In an embodiment, the first gas G1 may include air or oxygen. Accordingly, the first laser-induced graphene LIG1 overlapping the first area A1 may have hydrophilic properties.

Although not shown in FIG. 7, the forming the first laser-induced graphene LIG1 (S200) may be performed in a chamber in a vacuum atmosphere. In this case, irradiation of the carbon dioxide laser CDL and the first gas G1 is easy, so that the first laser-induced graphene LIG1 can be formed more effectively.

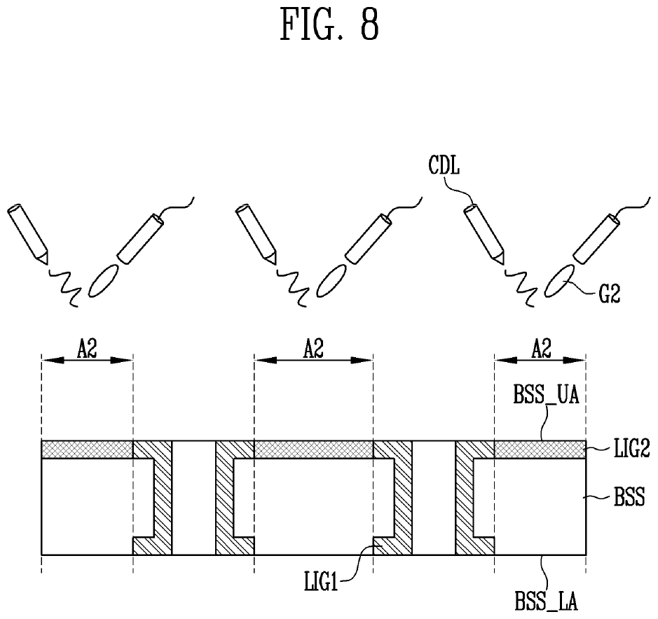

Referring to FIGS. 5 and 8, the manufacturing method of the display panel according to embodiments may further include forming second laser-induced graphene LIG2 (S300). According to an embodiment, the forming the second laser-induced graphene LIG2 (S300) may be omitted.

The second laser-induced graphene LIG2 may be formed by irradiating a carbon dioxide laser CDL together with a second gas G2 to a second area A2 overlapping a portion of the base substrate BSS spaced apart from at least one via hole VH.

The second area A2 may be an area that is adjacent to the first area A1 and does not overlap the first area A1. A portion of the base substrate BSS overlapping the second area A2 may include a portion of the upper surface BSS_UA of the base substrate BSS. That is, the portion of the base substrate BSS overlapping the second area A2 may be a portion of the upper surface BSS_UA of the base substrate BSS on which the first laser-induced graphene LIG1 is not formed. When the carbon dioxide laser CDL is irradiated to the second area A2 together with the second gas G2, the second laser-induced graphene LIG2 in contact with the first laser-induced graphene LIG1 may be formed on a portion of the upper surface BSS_UA of the base substrate BSS.

A wavelength of a laser beam irradiated from the carbon dioxide laser CDL may be the same as the wavelength of the laser beam in the forming the first laser-induced graphene LIG1 (S200).

In an embodiment, the second gas G2 may include at least one of argon and hydrogen. Accordingly, the second laser-induced graphene LIG2 overlapping the second area A2 may have water-repellent properties.

Although not shown in FIG. 8, the forming the second laser-induced graphene LIG2 (S300) may be performed in a chamber in a vacuum atmosphere. In this case, irradiation of the carbon dioxide laser CDL and the second gas G2 is easy, so that the second laser-induced graphene LIG2 can be formed more effectively.

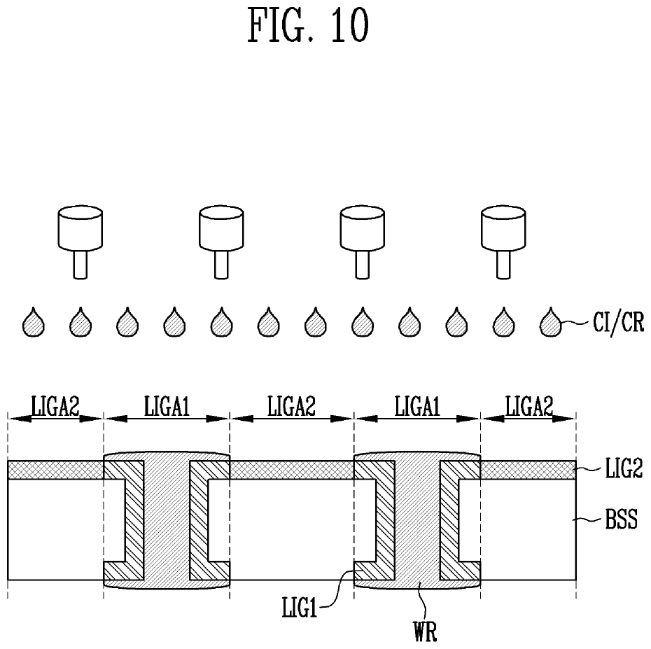

Referring to FIGS. 5, 9, and 10, the manufacturing method of the display panel according to embodiments may include forming at least one wiring WR corresponding to at least one via hole VH (see FIG. 6) (S400). FIG. 9 shows a method of forming at least one wiring WR corresponding to at least one via hole VH when the first laser-induced graphene LIG1 is formed. FIG. 10 shows a method of forming at least one wiring WR corresponding to at least one via hole VH when the first laser-induced graphene LIG1 and the second laser-induced graphene LIG2 are formed.

Referring to FIG. 9, a conductive material including at least one of conductive ink CI and conductive resin CR and having hydrophilic properties may be discharged to an area LIGA1 overlapping the first laser-induced graphene LIG1. The area LIGA1 overlapping the first laser-induced graphene LIG1 may overlap at least one via hole VH. The discharged conductive material may stick to the first laser-induced graphene LIG1 and fill at least one via hole VH. Thereafter, at least one wiring WR may be formed by drying and curing the conductive material filled in at least one via hole VH.

Referring to FIG. 10, the conductive material including at least one of conductive ink CI and conductive resin CR may be discharged to the area LIGA1 overlapping the first laser-induced graphene LIG1 and an area LIGA2 overlapping the second laser-induced graphene LIG2.

The conductive material discharged to the area LIGA2 overlapping the second laser-induced graphene LIG2 does not stick to the second laser-induced graphene LIG2 but moves to stick to the first laser-induced graphene LIG1. That is, even if the conductive material is discharged to the area LIGA2 overlapping the second laser-induced graphene LIG2, the conductive material may be fill in at least one via hole VH.

In the case of FIG. 9, because the conductive material must be discharged to the area LIGA1 overlapping the first laser-induced graphene LIG1, a range in which the conductive material is discharged may be limited. On the other hand, in the case of FIG. 10, since the conductive material can be discharged to areas other than the area LIGA1 overlapping the first laser-induced graphene LIG1, the range in which the conductive material is discharged can be expanded.

In accordance with embodiments, wirings connected to a data driving integrated circuit can be formed accurately and quickly on a display panel. Accordingly, the tact time of the display panel can be shortened.

While the present disclosure has been described with reference to embodiments thereof, it will be apparent to those of ordinary skill in the art that various changes and modifications may be made thereto without departing from the scope and spirit of the present disclosure as set forth in the following claims.

What is claimed is:

1. A display panel comprising:
a base substrate;
at least one via hole penetrating the base substrate; and
first laser-induced graphene formed on a first surface of the base substrate adjacent to the at least one via hole.

2. The display panel of claim 1, wherein the first laser-induced graphene has hydrophilic properties.

3. The display panel of claim 1, wherein the first surface includes a side surface, a portion of an upper surface, and a portion of a lower surface of the base substrate adjacent to the at least one via hole.

4. The display panel of claim 1, further comprising:
at least one wiring corresponding to the at least one via hole.

5. The display panel of claim 4, wherein the at least one wiring includes at least one of conductive ink and conductive resin.

6. The display panel of claim 4, wherein the at least one wiring is in contact with the first laser-induced graphene.

7. The display panel of claim 1, further comprising:
second laser-induced graphene formed on a second surface of the base substrate spaced apart from the at least one via hole and not overlapping the first surface.

8. The display panel of claim 7, wherein the second laser-induced graphene has water-repellent properties.

9. The display panel of claim 7, wherein the second surface includes a portion of an upper surface of the base substrate spaced apart from the at least one via hole.

10. The display panel of claim 9, wherein the second laser-induced graphene is in contact with the first laser-induced graphene.

11. A method of manufacturing a display panel including a base substrate, the manufacturing method comprising:
forming at least one via hole penetrating the base substrate; and
forming first laser-induced graphene by irradiating a carbon dioxide laser together with a first gas to a first area overlapping the at least one via hole and a portion of the base substrate adjacent to the at least one via hole.

12. The method of claim 11, wherein the first laser-induced graphene is formed on a side surface, a portion of an upper surface, and a portion of a lower surface of the base substrate adjacent to the at least one via hole.

13. The method of claim 11, wherein the first gas includes air or oxygen.

14. The method of claim 11, wherein the first laser-induced graphene has hydrophilic properties.

15. The method of claim 11, further comprising:
forming at least one wiring corresponding to the at least one via hole,
wherein the at least one wiring is in contact with the first laser-induced graphene.

16. The method of claim 11, further comprising:
forming second laser-induced graphene by irradiating a carbon dioxide laser together with a second gas to a second area spaced apart from the at least one via hole and overlapping a portion of the base substrate.

17. The method of claim 16, wherein the second laser-induced graphene is formed on a portion of an upper surface of the base substrate spaced apart from the at least one via hole.

18. The method of claim 16, wherein the second gas includes at least one of argon and hydrogen.

19. The method of claim 16, wherein the second laser-induced graphene has water-repellent properties.

20. The method of claim 16, further comprising:
forming at least one wiring corresponding to the at least one via hole,
wherein the at least one wiring is in contact with the first laser-induced graphene and does not contact the second laser-induced graphene.
